(19) United States
(12) Patent Application Publication
(10) Pub. No.: US 2009/0315551 A1
(43) Pub. Date: Dec. 24, 2009

(54) Linear magnetoresistance sensor

(76) Inventors: Jingshi Hu, Revere, MA (US); Thomas F. Rosenbaum, Wilmette, IL (US)

Correspondence Address: BRINKS HOFER GILSON & LIONE, P.O. BOX 10395, CHICAGO, IL, 60610, US

(21) Appl. No.: 12/456,797

(22) Filed: Jun. 22, 2009

Related U.S. Application Data
(60) Provisional application No. 61/074,346, filed on Jun. 20, 2008.

(51) Int. Cl. G01R 33/09

(52) U.S. Cl. 324/252

(57) ABSTRACT

A linear (or substantially linear) magnetoresistance sensor is provided. The magnetoresistance sensor may use one of the following magnetotransport mechanisms: classical magnetoresistance (MR) or quantum MR effects. In the classical regime, the sensor may be composed of a polycrystalline narrow gap semiconductor that has a varying mobility (instead of a constant mobility). The material's varying mobility enables the magnetoresistive sensor to have: (1) a linear magnetoresistance; (2) a high temperature response; and (3) an ability to respond to the highest possible fields. In the quantum regime, the sensor may be composed of a single crystal narrow gap semiconductor that is sufficiently doped so that the material may exhibit a linear response in a temperature range of 50K-175 K.

### RELATED APPLICATION

The present patent document claims the benefit of the filing date under 35 U.S.C. §119(e) of Provisional U.S. Patent Application Ser. No. 61/074,346, filed Jun. 20, 2008, which is hereby incorporated by reference herein in its entirety.

### FEDERALLY SPONSORED RESEARCH OR DEVELOPMENT

This invention was made with government support under DE-FG02-99ER45789 awarded by the U.S. Department of Energy. The government has certain rights in the invention.

### BACKGROUND

Magnetoresistance is the property of a material to change the value of its electrical resistance when an external magnetic field is applied to it. Sensors may use the magnetoresistive property of the material to relate the externally applied magnetic field with an electrical resistance.

Magnetoresistive sensors may measure several conditions, including linear and angular displacement, rotational speed measurement, and current measurement. And, the magnetoresistive sensors may be used in a variety of applications, including automotive applications (such as angular position sensors for an internal combustion engine, wheel speed sensors for ABS, and position sensors for chassis position and throttle position measurement), electronic compasses, earth field correction applications, and traffic detection applications. Examples of magnetoresistive sensors include tunnel junctions, spin valves, anisotropic magnetoresistive (AMR) sensors, extraordinary Hall effect sensors and the like.

In semiconductors used for the magnetoresistance sensors, the resistance of the semiconductor is proportional to the square of the applied magnetic field, as shown by the below equation:

$$\frac{Δ ρ}{ρ} ∝ \{ \begin{matrix}{( μ H )}^{2} , & μ H < 1 T \\ C , & μ H > 1 T ,\end{matrix} \qquad ( 1 )$$

As evident from Eq. 1, the electrical resistivity p is dependent quadratically on the magnetic field H. Further, the magnetoresistance sensors saturate when low fields are applied (such as magnetic fields on the order of 1 tesla).

At times, a linear magnetoresistive response of the magnetoresistive sensor is desired. In order to compensate for the non-linear magnetoresistive characteristics (as well as to compensate for the inability to detect the polarity of a magnetic field), the structure of magnetoresistive sensors may be rather complex. In particular, the sensors may include stripes of aluminum or gold placed on a thin film of permalloy (such as a ferromagnetic material exhibiting the AMR effect) inclined at an angle of 45° in order to linearize the magnetoresistive effect. This structure forces the current not to flow along the “easy axes” of thin film, but at an angle of 45°. The dependence of resistance now has a permanent offset which is linear around the null point. Because of its appearance, this sensor type is called “barber pole.” What is needed is a magnetoresistive sensor that is less complex in structure than prior magnetoresistive sensors. What is also needed is a magnetoresistive sensor that does not saturate at lower applied fields (such as 1 tesla).

### BRIEF SUMMARY

The present invention is defined by the attached claims, and nothing in this section should be taken as a limitation on those claims. In order to address the one or more needs discussed above, described below is a linear (or substantially linear) magnetoresistance sensor. The sensors may use one of the following magnetotransport mechanisms: classical magnetoresistance (MR) or quantum MR effects.

In the classical regime, the sensor may be composed of a semiconductor, such as a polycrystalline semiconductor, that has a varying mobility (instead of a constant mobility). The material's varying mobility enables one or more features of the magnetoresistive sensor including: (1) linearity of the magnetoresistance; (2) high temperature response; and (3) ability to respond to very large applied magnetic fields.

First, because of the varying mobility, the magnetoresistive response may be dependent or determined by the variations in the mobility (such as by the distribution of mobilities in the semiconductor), rather than controlled by the carrier mobility. One example of a varying mobility may comprise a material with a distribution of the mobilities (such as a Gaussian distribution centered at 0 mobility with a Δμ standard deviation). And, because the material has a varying mobility, the magnetoresistive effect is not as recited in Eq. 1. Rather, the magnetoresistive effect may be dependent on ΔμH. Unlike Eq. 1 (which is dependent on (μH)²), the magnetoresistive effect is linear due to the varying mobilities of the material. In this way, the magnetoresistive sensor using the polycrystalline material as described may exhibit a linear (or substantially linear) response without the need for the complicated structures of the prior art.

Second, the magnitude of the MR for the disclosed magnetoresistive sensor may be dominated by distribution of mobilities over a wide temperature range. Specifically, the magnetoresistive response using the material as disclosed does not decrease (and may stay constant and/or increase) as the temperature increases. So that, the temperature range in the classical regime may be from approximately 200K up to the melting point of the material used for the magnetoresistance sensor. This is in contrast to prior art materials used for magnetoresistance sensors, which may exhibit a decreased magnetoresistive response as the temperature increases, thereby limiting the temperature range in which the magnetoresistive sensor may be operated.

Third, with regard to applied magnetic field, the material used for the magnetoresistive sensor may not saturate even for very large applied magnetic fields, such as 50 tesla, 60 tesla, 100 tesla, or greater. In this way, the magnetoresistive sensor may be used as a megaGauss sensor (such as in pulsed magnets). This is unlike typical magnetoresistive sensors, which may saturate starting at approximately 1 tesla, severely limiting the range of applied magnetic fields that may be sensed using the magnetoresistive sensor.

The material used in the magnetoresistance sensor may comprise a narrow gap semiconductor, such as InSb (indium antimonide). Further, the material may be configured with varying mobility in one of several ways. One way is by grinding single-crystal InSb into a fine powder and then heating (or annealing) the powder at a temperature just below the melting point of InSb.

In the quantum regime, the sensor may be composed of a narrow gap semiconductor, such as a single crystal InSb, that is doped by adding a few parts per million of the proper chemical impurities to InSb. The magnetoresistance sensor using this material may exhibit a linear response in a temperature range of 50K-175 K. In this way, the magnetoresistance sensor may capitalize on the unusual electronic properties of the narrow gap semiconductor that result from a low carrier concentration (via optimal doping), a small conduction electron effective mass, a large Fermi wavelength, and an extremely long carrier mean free path.

The following description will now be described with reference to the attached drawings.

### BRIEF DESCRIPTION OF THE DRAWINGS

FIG. 1A is a plot showing variation of carrier concentration (n) with temperature (T) deduced from Hall effect measurements for an exemplary InSb single crystal specimen;

FIG. 1B is a plot showing zero-field resistance (R) versus temperature (T) for an exemplary InSb single crystal specimen, and the inset shows In(p) as function of 1/T at H=0, where the solid lines represent low and high temperature slopes;

FIG. 2A is a plot of transverse magnetoresistance normalized to its zero-field value (ΔR(H)/R) as a function of the applied field (H) for an exemplary InSb single crystal specimen, with the inset showing low-field magnetoresistance at selected temperatures (50K, 90K, 130K, 175K);

FIG. 2B is a plot of ΔR(H)/R versus H for n-type InSb at a temperature of 175 K in a longitudinal magnetic field;

FIG. 2C is a plot of ΔR(H)/R versus H² for n-type InSb showing the usual quadratic magnetic field dependence of the MR that characterizes the intrinsic regimes at low and high temperatures;

FIG. 2D is a schematic of the “extreme quantum limit,” when only one or two Landau bands are filled;

FIG. 3A is a schematic showing the effect of inhomogeneity on the conduction and valence bands of InSb;

FIG. 3B is a plot of ΔR(H)/R versus H for an exemplary polycrystalline InSb specimen from temperatures ranging from 200K to 350K, where the inset is a scanning electron microscope (SEM) image of InSb with a grain size of about 10-20 microns;

FIG. 4A shows the transverse MR of an exemplary polycrystalline InSb specimen for temperatures ranging from 200K to 400K;

FIG. 4B shows the transverse MR of an exemplary single crystal InSb specimen for temperatures ranging from 200K to 400K; and

FIG. 5 shows a block diagram of an exemplary magnetic sensor comprising a narrow gap semiconductor.

### DETAILED DESCRIPTION

Sensors with a linear (or substantially linear) magnetoresistance are provided. The sensors may use one of the following magnetotransport mechanisms: classical magnetoresistance or quantum MR effects. In the classical regime, the sensor may be composed of a semiconductor, such as a polycrystalline semiconductor, that has a varying mobility (instead of a constant mobility). In this way, the magnitude of the MR may be dominated (or determined) by the variations in the mobility (such as by the distribution of mobilities in the semiconductor), rather than controlled by the carrier mobility, so that the magnetoresistance is linear (or substantially linear). As discussed in the background, the resistance of typical MR sensors is proportional to the square of the applied magnetic field due to the dependence of the magnetoresistance on the semiconductor mobility p. See Eq. 1. To compensate for the non-linear magnetoresistance, complicated structures for the sensors are required. In contrast, the material used in the classical MR sensor of the present invention is configured so that the mobility varies in the material. One example of a varying mobility, discussed below, may comprise a material with a distribution of the mobilities (such as a Gaussian distribution centered at 0 mobility with a Δμ standard deviation). And, because the material has a varying mobility, the magnetoresistive effect is not as recited in Eq. 1. Rather, the magnetoresistive effect may be dependent on ΔμH. Unlike Eq. 1 (which is dependent on (μH)²), the magnetoresistive effect is linear due to the varying mobilities of the material. In this way, the magnetoresistive sensor using the polycrystalline material as described may exhibit a linear (or substantially linear) response without the need for the complicated structures of the prior art.

And, the magnitude of the MR for the disclosed magnetoresistive sensor may be dominated by distribution of mobilities over a wide temperature range and a wide range of externally applied magnetic fields, as discussed in more detail below. With regard to temperature, the magnetoresistive response using the material as disclosed does not decrease (and may stay constant and/or increase) as the temperature increases. So that, the temperature range in the classical regime may be approximately at 200K up to the melting point of the material used for the magnetoresistance sensor. This is in contrast to prior art materials used for magnetoresistance sensors, which may exhibit a decreased magnetoresistive response as the temperature increases, thereby limiting the temperature range in which the magnetoresistive sensor may be operated. Further, with regard to applied magnetic field, the material may not saturate even for very large applied magnetic fields, such as 50 tesla, 60 tesla, 100 tesla, or greater. This is unlike typical magnetoresistive sensors. As described in the background, the typical magnetoresistive sensors may saturate starting at approximately 1 tesla. This severely limits the range of applied magnetic fields that may be sensed using the magnetoresistive sensor. In this way, the disclosed magnetoresistive sensor may exhibit a linear (or substantially linear) response over a large temperature range and a large range of externally applied magnetic fields.

For the material's magnetoresistance to be dominated by the distribution of the mobilities, the mobility in the material may be sufficiently varied, such as by having a Gaussian distribution of the mobilities preferably centered approximately at 0 with a Δμ standard deviation. The material for the sensor may be made in a variety of ways so that the material has a sufficiently varying mobility. In particular, the material's structure may be redesigned on the micrometer scale in order to configure the proper distribution of mobilities, as discussed in more detail below. In this way, the modification of the material may result in a classical outgrowth of disorder, turned to advantage. Further, the characteristics of the magnetoresistance of the material may be modified based on the construction of the material. As discussed in more detail below, the material may have a disordered or inhomogeneous structure on the microscale which includes grains separated by grain boundaries and one or more elements preferentially segregated to the grain boundary regions. Modifying the grain size and/or the relative size of the grain boundary to the volume may change the characteristics of the magnetoresistance, including the temperature onset of the linear magnetoresistance and/or the magnitude of the magnetoresistance effect.

In the quantum regime, the material may be made by adding a few parts per million of the proper chemical impurities to a narrow gap semiconductor, such as InSb.

In both cases, the magnetoresistive response—at the heart of magnetic sensor technology—may be converted to a simple, large and linear function of field that does not saturate even under very large applied magnetic fields. Harnessing the effects of disorder has the further advantage of extending the useful application range of such a magnetic sensor to very high temperatures by circumventing the usual limitations imposed by phonon scattering.

The magnetic sensor may include a material that acts as an MR sensing element and comprises a narrow gap semiconductor, i.e., a semiconductor having a bandgap that is small compared to that of silicon. The narrow gap semiconductor may include one or more of the following elements: In, Sb, As, Ag, Pb, Se, S, Te, Hg, Cd, Bi, Sn, or others. In addition, the narrow gap semiconductor may be a stoichiometric compound of two or more of the preceding elements, or it may be an off-stoichiometric compound. For example, the semiconductor may be InSb, InAs, Ag₂Se, Ag₂Te, PbSe, PbS, PbTe, HgCdTe, Cd3As₂, Bi₂Te₃, or α-Sn.

With regard to the quantum effect, a narrow gap semiconductor with single crystals may be used. Preferably, the narrow gap semiconductor is InSb, which has a near zero bandgap and has the advantages of unusual electronic properties that result from a low carrier concentration, a small conduction electron effective mass, a large Fermi wavelength, and an extremely long carrier mean free path.

With regard to the classical effect, a narrow gap polycrystalline semiconductor may be used. Preferably, the narrow gap semiconductor is InSb, The material selected may take advantage of the narrow gap, the linear band structure in the immediate vicinity of the band crossing, the distribution of mobilities, and a high melting point (such as 527 ° C. in InSb). In a narrow gap semiconductor such as InSb, the distribution of mobilities is dependent on the dominant carrier present. For example, if the dominant carrier is electrons, the mobility is negative. Similarly, if the dominant carrier is holes, the mobility is positive. So that, the sign of the mobility may change depending on the type of dominant carrier. And, the shape of the distribution of the mobilities may be affected by the band structure of the narrow gap semiconductor. More specifically, the band structure in the immediate vicinity of the band crossing is linear (or approximately linear) so that the distribution is dominated by this linearity of the band structure at the band crossing. These characteristics may enable both quantum linear MR and inhomogeneity-induced classical MR, using single crystal and polycrystal InSb respectively.

For a sensor exhibiting the quantum linear MR effect, the sensing element may comprise a single crystal narrow gap semiconductor, preferably single crystal InSb. High quality single crystals of InSb may be grown epitaxially or from a melt. For example, single crystal InSb may be grown from a melt containing 48.6% In and 51.4% Sb. Excess Sb atoms are sublimated from the lattice and transported to the crystallization front, producing perfectly stoichiometric InSb with droplets of single-phased Sb on the semiconductor surface of the single crystal. Even if impurities are not added to the melt intentionally, shallow, effective-mass like donors are always present in concentrations of at least 10¹⁷ cm⁻³, effectively dominating the conductivity below 175 K due to their small binding energy (E_{b}=0.6 meV). Alternatively, the sensing element may be configured using uniaxial stress.

Advantageously, the single crystal InSb is lightly doped so that the semiconductor includes substantially only one carrier type. Previous studies on InSb in the prior art have focused on heavily doped and compensated samples with multiple carrier species; the resulting magnetotransport involving two types of holes and the complications of impurity band conduction. The single crystal InSb employed for the present magnetic sensor is preferably n-type and thus the majority of carriers are negatively charged (electrons). For example, the single crystal InSb may include about 10⁻⁵ conduction electrons per unit cell. Despite the low carrier concentration, the resistivity of the InSb is only about 50 times that of copper, which is an indication of its large relaxation time (the low-field Hall mobility, μ_{H}=2.2 m²/Vs at T=300 K). Single crystal InSb may thus be employed in magnetic sensors that exploit the quantum linear MR effect, as discussed further below.

For a sensor exhibiting the classical linear MR effect, the sensing element may comprise a polycrystalline narrow gap semiconductor, preferably polycrystalline InSb. Such materials have a disordered or inhomogeneous structure on the microscale which includes grains separated by grain boundaries and one or more elements preferentially segregated to the grain boundary regions. The segregated element(s) may be an excess constituent of the semiconductor (e.g., Sb) or an impurity element. Polycrystalline InSb samples may be prepared from nanopowders obtained from the single crystalline material, for example. For example, single-crystal InSb prepared as described above may be ground into a fine powder and then heated (or annealed) at a temperature just below the melting point of InSb. The process may be carried out in a controlled environment, for example, an atmosphere of 95% N₂ and 5% H₂. When heated, the powder particles may sinter together to form a polycrystalline bulk material, which may include grains of length scale 0.1 to 100 microns in size (or more preferably 1 to 10 microns or 10 to 20 microns) separated by grain boundaries. In this way, the polycrystalline material may be viewed as a plurality of single crystals of length approximately 0.1 to 100 microns in size, with the plurality of single crystals having different mobilities (thereby creating the mobility distribution in the material). The excess Sb employed to form the single crystal InSb may segregate to the grain boundaries, which produces microscopic inhomogeneities in the specimens. The network of grain boundaries, including the excess Sb, may provide random conduction paths through the semiconductor. An increase in grain boundary volume fraction may increase the current distortion. The grain size of the polycrystalline material may range, for example, from a few microns to tens of microns and may have an impact on the size of the magnetic field required for the onset of linear MR. In general, at smaller grain sizes, larger magnetic fields may be needed to initiate the linear behavior. Polycrystalline InSb is employed in magnetic sensors that exploit the classical linear MR effect, as discussed further below. Alternatively, the polycrystalline InSb samples may be prepared by using sputtering or another deposition process, or by patterning (such as creating random or pseudo random conduction paths through the semiconductor using patterning).

As discussed in the background, symmetry conditions demand a quadratic dependence of the electrical resistivity p on magnetic field H in the low field limit.

Sufficiently strong disorder, where current paths no longer align with the applied voltage, may also mix the components of the resistivity tensor in such a way as to escape the strictures of Eq. 1, whether or not the material has an intrinsic physical MR. A design feature of this new regime is that the magnitude of the MR is no longer controlled by the carrier mobility, but rather by the distribution of mobilities, with the biggest response occurring near band crossing where μ→0 and both positive and negative mobilities can be sampled.

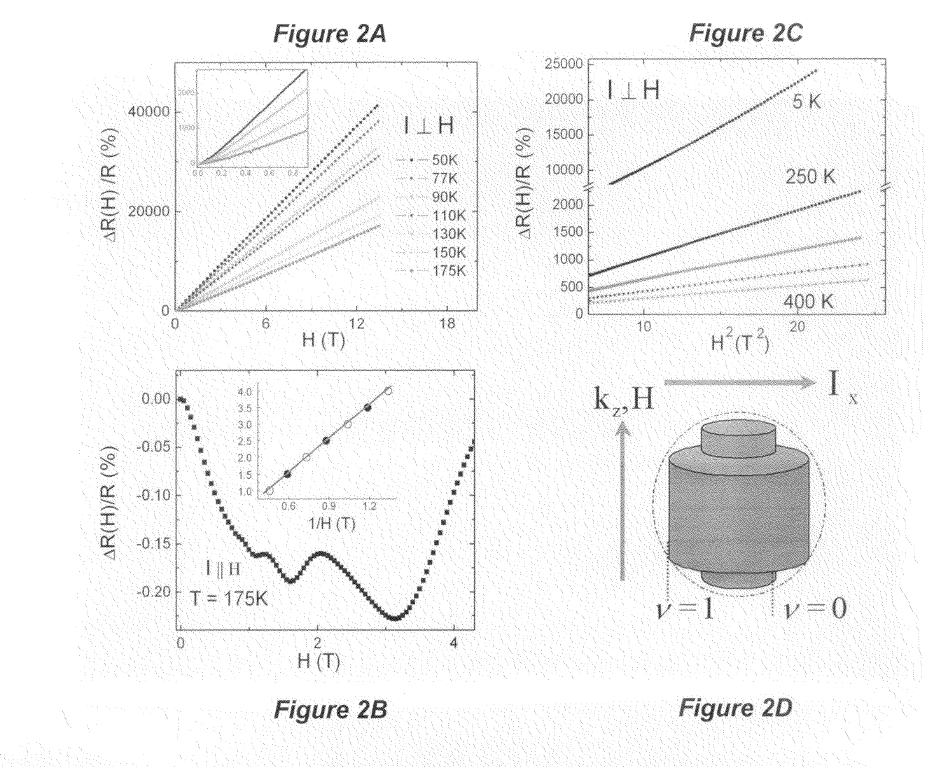

Of particular interest for technological applications is the MR at and above room temperature. The classical, orbital MR above 200 K (FIG. 2C, which is discussed below) is controlled by the dimensionless parameter involving the product of the carriers' mobility and magnetic field, ω_{c}τ=μH, where the cyclotron and effective masses are equal for the simply, parabolic band structure of n-type InSb. Under usual circumstances, the magnitude of the MR diminishes rapidly with increased phonon scattering at higher temperatures and the sensitivity diminishes rapidly in all conventional devices. However, it is possible to engineer an exception to this limitation by tapping the benefits of disorder. When gross inhomogeneities exist in a semiconductor—whether or not the material has an intrinsic, physical MR—it is possible to create distorted current paths misaligned with the driving voltage, and mix in the off-diagonal components of the magnetoresistivity tensor. As a result, the associated magnetotransport is dominated by the magnitude of the fluctuations in the mobility, Δμ, rather than the mobility μ itself. The purely classical, geometric effects of micron-long nanowires of excess Ag may be responsible for the non-saturating, linear MR in Ag_{2±δ}Se and Ag_{2±δ}Te. In this way, the magnetoresistivity effect of the material may increase as the temperature increases.

Quantum Effect

Quantum effects become noticeable when the individual quantum levels associated with the electron orbits are distinct: ω_{c}>>k_{B}T, where ω_{c} is the cyclotron frequency and T is the temperature.

At still higher magnetic fields, it is possible to reach the “extreme quantum limit,” where ω_{c} can exceed the Fermi energy, E_{F}, and electrons can coalesce into the lowest quantum state of the transverse motion in H. A generic quantum description of galvanomagnetic phenomena was developed by Abrikosov, with:

$${ρ}_{xx} = {ρ}_{yy} = \frac{{N}_{i} H}{π {n}^{2} ec} ∝ H , \qquad ( 2 )$$

where ρₓₓ and ρₓₓ are the transverse components of the MR, n is the density of electrons, and Nᵢ is the concentration of static scattering centers. This quantum MR is linear down to very small fields, positive, and non-saturating. However, the necessity of reaching the extreme quantum limit makes practical realizations unique to half-metals and to semiconductors having tiny pockets of the Fermi surface with a small effective mass.

In suitably doped n-type single-crystal InSb, a remarkably large MR effect of up to 40,000% with a field sensitivity of 0.2%/Oe has been realized for the limiting quantum case. The effect is nearly two orders of magnitude larger than the classical MR effects found in Ag_{2±δ}Se, which suggests that single-crystal InSb may be a preferred material for magnetic field sensing within an intermediate temperature range (50K-175 K).

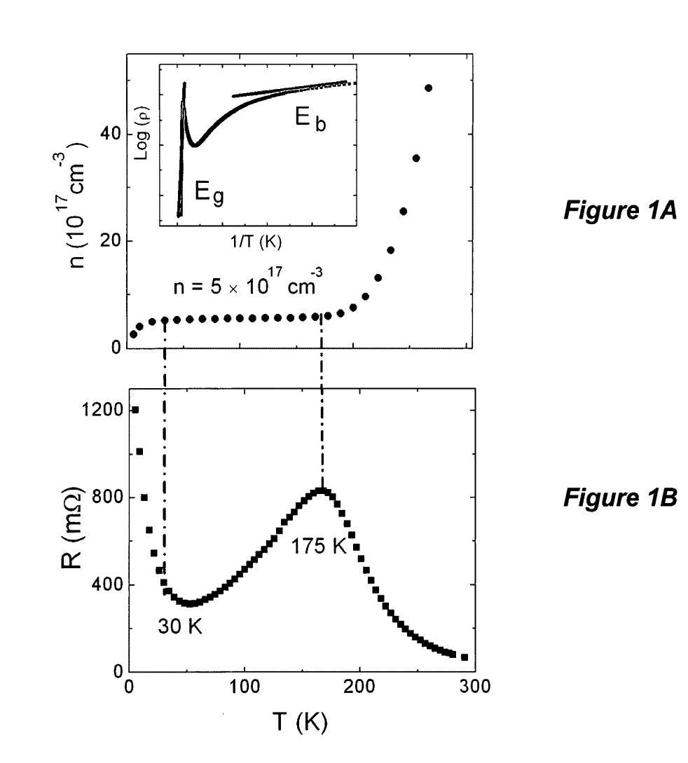

FIGS. 1A and 1B compare the temperature dependence of the zero-field resistance and the carrier concentration derived from measurements of the Hall effect, assuming a one-band model. The n-type donors are Bi and Pb, as confirmed by mass spectroscopy. Between T=30 K and 175 K, all the impurity donors are thermally activated, leading to a metallic conductivity with extrinsic carrier concentration independent of temperature (n=N_{D}=5×10¹⁷ cm⁻³). The resistivity decreases with decreasing temperature due to decreased phonon scattering. At temperatures above and below the extrinsic regime, activated behavior dominates the resistivity. At higher temperatures, the intrinsic carrier concentration n, becomes larger than N_{D}, and the resistivity decreases exponentially with temperature in accordance with the usual behavior of intrinsic semiconductors, ρ(T)∝exp(E_{g}/2kT), with the band gap energy E_{g}=200 meV (FIG. 1A, inset). As the donors freeze out below 30 K, the resistivity again exhibits an exponential dependence on T, ρ(T)∝exp(E_{b}/2kT), but with a shallower slope than that at high temperatures because the n-type donors Pb and Bi have binding energies E_{b}=0.6 meV<<E_{g}.

The regime of extrinsic conductivity, depicted as the plateau in FIG. 1A, is characterized by a constant number of degenerate electrons with a quadratic, isotropic dispersion relation, and a small effective mass of 0.01 m₀ (m₀ being the free electron mass). This yields a large Dingle temperature, T_{D}=200 K, for H=2 T (ω_{c}>>k_{B}T), and the quantum linear MR emerges.

The transverse MR normalized to its zero-field value rises linearly with magnetic field in the extrinsic temperature regime, as shown in FIG. 2A, which plots the positive, linear magnetic field dependence of the transverse MR. The size of the effect is huge, exceeding 40,000% by H=13 T at T=50 K. Of particular interest is the temperature dependence of the linear response, which decreases only by a factor of 2 (still of order 20,000% at H=13 T) as the temperature varies from 50 K to 175 K. This relative insensitivity to T demonstrates that the magnitude of the linear MR is not due to the appearance of phonon scattering, which should lead to a marked decrease with increasing T, but is most likely associated with the concentration of scattering centers, Nᵢ. This behavior is qualitatively confirmed by the theoretical expression given in Eq. 2. Low field MR at selected temperatures (50K, 90K, 130K, 175K) indicates a crossover to quadratic behavior as H→0, as shown in the inset of FIG. 2A.

The explicit quantum nature of the response can be discerned from the observation of an oscillatory magnetic field response in the low field MR. This effect, known as Shubnikov-deHaas oscillations, indicates the modulated density of states at the Fermi surface as a quantized Landau level sweeps through the Fermi energy. FIG. 2B plots Shubnikov-deHaas oscillations for an exemplary crystal of n-type InSb. A longitudinal configuration may be required to observe the oscillatory behavior because the background MR in a longitudinal field is approximately 10⁴ times smaller than its transverse counterpart. The observed oscillations provide clear evidence of Landau quantization over the entire temperature range of the quantum linear MR (30K-175K). Referring to the inset of FIG. 2B, the peaks (filled circles) and valleys (open circles) of the oscillations scale as expected with 1/H, with all the conduction electrons in the lowest Landau level for H>2.5 T, when the material is in the “extreme quantum limit.” The solid line is a linear fit to 1/H, characteristic of Landau level physics. Somewhat surprisingly, the crossover from quadratic to linear dependence on magnetic field at H=0.7 T is considerably lower than the predicted value from the condition ω_{c}>E_{F}, pointing to an early emergence of the linear MR when not strictly only the lowest, but 2 or 3 quantized levels are involved (FIG. 2D). As demonstrated in FIG. 2C, the quadratic magnetic field dependence of the MR re-emerges in the intrinsic regime above T=200 K when holes compensate the conduction and the Landau levels smear out rapidly from both thermal and collision broadening. At lower temperatures, the quantum effect breaks down for T<10 K because the electrons freeze out and the semiconductor becomes non-degenerate. With high-level control over the impurity doping levels, one can readily anticipate sensors with substantially enhanced quantum linear MR over an even greater temperature range.

Classical Effect

Of particular interest for technological applications is the MR effect approximately at/above room temperature. InSb is a potential candidate for a robust, responsive, high-temperature MR device because of its large magnetic g-factor (inversely proportional to the low effective mass) and because the absolute value of the classical linear MR, which can be directly related to the Hall voltage, tracks InSb's low electron concentration. Unlike the silver chalcogenides, however, InSb is known for its large, intrinsic MR. Consequently, the presence of inhomogeneities leads to a linear MR that will trump a quadratic MR only at temperatures sufficiently high for the intrinsic MR to be quenched by phonon scattering.

The classical linear MR observed in polycrystalline InSb is favorable for wide-range field and current sensing in this high temperature regime. The reasons are two fold: (1) Ag_{2±δ}Se undergoes a first order phase transition to the super-ionic α-phase around 400 K, while InSb remains structurally stable up to 800K. (2) The magnetoresistance of silver chalcogenides evolves to a slightly super-linear field dependence above 250 K. The MR effects in polycrystalline InSb, on the other hand, boast a robust linear dependence on magnetic field up to 400K, and are larger than that of Ag_{2±δ}Se by at least a factor of 8.

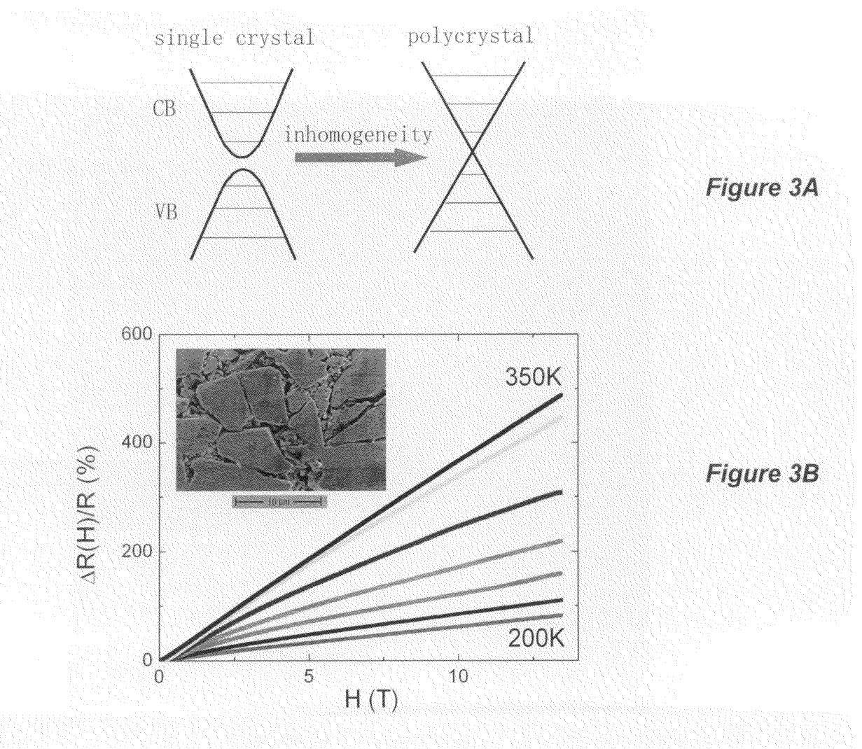

FIG. 3B plots the normalized, transverse MR of polycrystalline InSb, measured up to H=14 T for 200 K≦T≦350 K (i.e., above the quantum regime). The MR of the inhomogeneous material is comparable to that of the pure crystal, and rises linearly with magnetic field, in agreement with the picture of inhomogeneous conductance. The fact that the MR actually increases with T presumably reflects the dominance of the response by Δμ. The disorder induced by nonstoichiometry transforms a narrow-gap semiconductor into a hybridized gapless state with linear energy spectrum in both the valence and conduction bands. The resulting band structure, depicted in FIG. 3A, is analogous to that of single-layer graphite (graphene) in the vicinity of the Dirac Point (differing only in dimensionality), where the predominant concentrations of electrons or holes are induced by positive/negative gate voltages. The mobility fluctuations in the present system are particularly acute when the gap goes to zero and both positive and negative values can be sampled, an effect that becomes increasingly more effective as temperature rises. For an inhomogeneous system, however, the averaged mobility cannot be simply obtained from a measurement of the Hall resistance. The experimental determination of the mobility distribution requires a more precise characterization of the internal structure. Fits to the PL model yield <μ>=0 and Δμ⁻¹=0.5 T, confirming that the observed crossover field is set by the width of the mobility fluctuations. The fact that the electrons and holes are present in equal proportions, as indicated by <μ>=0, is consistent with the assertion that the MR is most linear when both positive and negative values of the mobility can be sampled. The inset of FIG. 3B is an SEM image of an InSb polycrystal with a typical grain size of 10-20 microns. The inter-grain resistance can be estimated by contrasting the zero-field resistivity of single crystal and polycrystal InSb in their regimes of intrinsic conductivity (e.g., at T=300K), where intrinsic carrier number and phonon scattering dominate the conductivity. The inter-grain resistivity is found to be 9×10⁻³ Ω·cm, approximately an order of magnitude higher than the resistivity of the pure crystal.

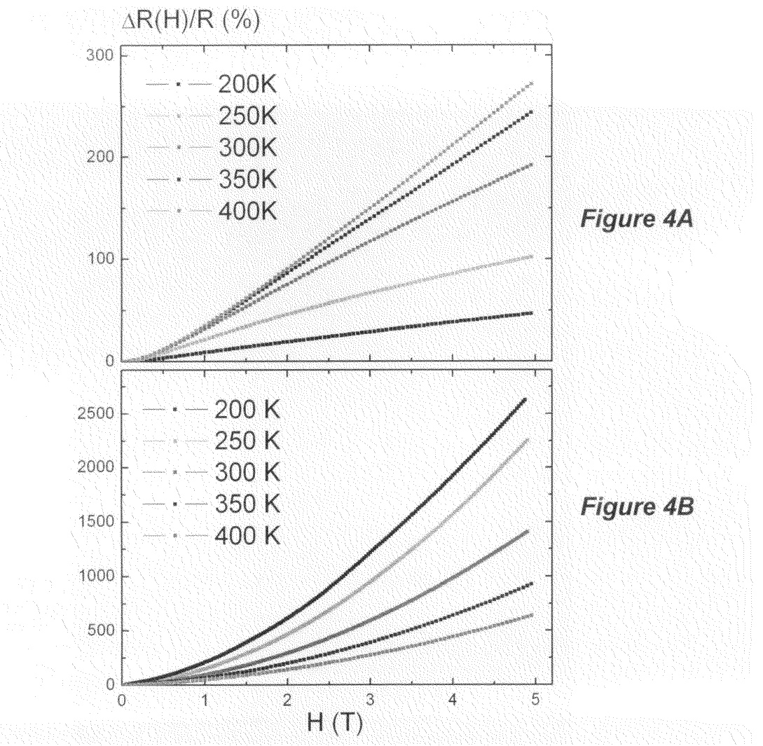

FIGS. 4A and 4B contrast the normalized transverse MR of polycrystalline and single crystal InSb from 200K to 400K (i.e., away from the quantum regime). In this temperature range, the intrinsic MR of the single-crystal follows a quadratic magnetic field dependence, and decreases rapidly with increasing temperature. On the other hand, the magnetoresistive response of the inhomogeneous material is an order of magnitude smaller than that of the pure crystal, but rises linearly with magnetic field, in perfect agreement with the picture of inhomogeneous conductance. Below 200 K, the observed MR has a super-linear magnetic field dependence, because it rises from two contributions, namely the classical linear MR and the physical effects of the material itself.

The classical linear MR observed in polycrystalline InSb is greatly surpassed by the quantum effects observed below 175 K, but it is favorable for wide-range field and current sensing in the high T regime. The enhancement of the field sensitivity may not continue to increase greatly above T=400 K given the observed trend in FIG. 3B, but it should have considerable high temperature head room given that InSb does not melt until 800 K. This hardy behavior is in sharp contrast to homogeneous materials where rapidly decreasing carrier mobility with increasing T kills the MR. Thus, it holds appeal for applications in ceramic engines for automobiles and airplanes, as well as high field, non-saturating sensors for research at high T.

Moreover, devices with still higher inhomogeneous MR may be achievable with artificially fabricated hybrid structures and conducting networks. A geometric technique may massively enhance the low field MR of a composite InSb disk with metallic inclusions. Such an approach may be used for room temperature magnetic sensors, but differs from the linear MR in the underlying mechanism (dependence on the intrinsic MR of InSb), functional form (quadratic with field) and limiting field (saturating at H˜5 T). Graphene based heterostructures may also be beneficial thanks to their exceptionally large Hall coefficients and built-in gapless states. The charge density in graphene FETs may be mesoscopically inhomogeneous, and can be viewed as a checkerboard of n- and p-type doped regions separated by weakly conducting p-n junctions. Interestingly, manipulation of current flows may be achieved by fine-tuning the density of carriers and gate voltages on both sides of the p-n junctions. On these grounds, spatial variations of the effective gate voltage may induce pronounced mobility fluctuations and, consequently, a non-saturating linear MR in a more controlled fashion.

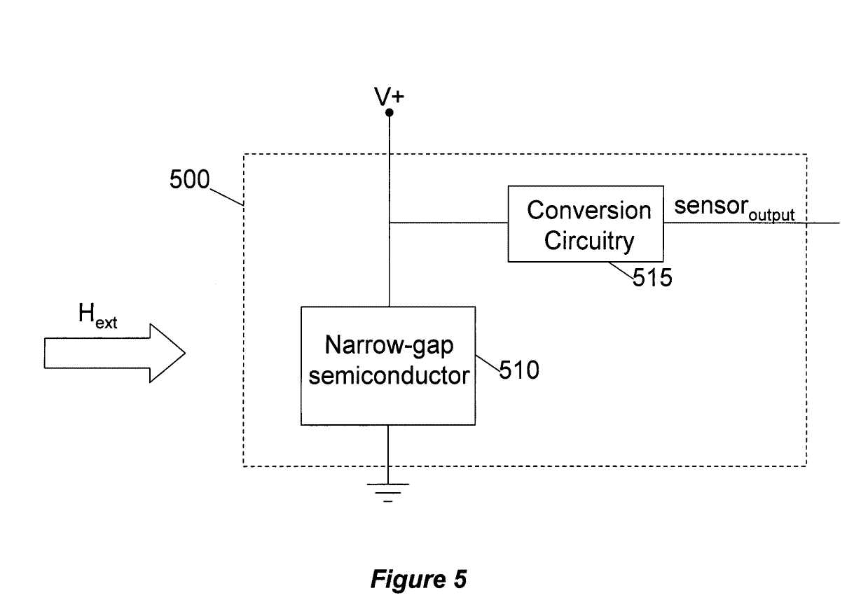

FIG. 5 shows a block diagram of an exemplary magnetic sensor 500 comprising a narrow gap semiconductor 510. For a sensor exhibiting the classical linear MR effect, the narrow gap semiconductor 510 may include a distribution of mobilities that is approximately centered around 0. In this way, the magnetoresistive response of the narrow gap semiconductor 510 may be dominated by the distribution of the mobilities (instead of the mobility itself) so that the magnetoresistive response of the narrow gap semiconductor 510 may be linear (or substantially linear) at temperatures at approximately room temperature to approximately the melting point of the narrow gap semiconductor 510. For a sensor exhibiting the quantum MR effect, the narrow gap semiconductor 510 may be doped as described above. The narrow gap semiconductor 510 may include leads (not shown) for connection to power (V+), ground, or other electrical elements.

The magnetic sensor 500 may sense an externally applied magnetic field Hₑₓₜ and, using conversion circuitry 515, output an electrical signal (sensorₒᵤₜₚᵤₜ) that is an indicator of the externally applied magnetic field Hₑₓₜ. For example, narrow gap semiconductor 510 may change its resistance in response to the externally applied magnetic field Hₑₓₜ. Conversion circuitry 515 may sense the change in resistance of narrow gap semiconductor 510 and output sensorₒᵤₜₚᵤₜ. Conversion circuitry may include one or more of an amplifier (such as a differential amplifier), comparator, or the like. Because narrow gap semiconductor 510 has a linear or substantially linear magnetoresistive response, sensorₒᵤₜₚᵤₜ may be correlate the externally applied magnetic field Hₑₓₜ to sensorₒᵤₜₚᵤₜ in a linear or substantially linear manner.

Sensor 500 may measure several conditions, including linear and angular displacement, rotational speed measurement, and current measurement. Further, sensor 500 may be used in a variety of applications, including automotive applications (such as angular position sensors for an internal combustion engine, wheel speed sensors for ABS, and position sensors for chassis position and throttle position measurement), electronic compasses, earth field correction applications, and traffic detection applications.

Although the present invention has been described in considerable detail with reference to certain embodiments thereof, other embodiments are possible without departing from the present invention. The spirit and scope of the appended claims should not be limited, therefore, to the description of the preferred embodiments included here. All embodiments that come within the meaning of the claims, either literally or by equivalence, are intended to be embraced therein. Furthermore, the advantages described above are not necessarily the only advantages of the invention, and it is not necessarily expected that all of the described advantages will be achieved with every embodiment of the invention.

1. A sensor for measuring a magnetic field, the sensor comprising:
a polycrystalline semiconductor having a linear or substantially linear magnetoresistive response over at least a temperature range, the semiconductor being configured with varying mobility such that the varying mobility dominates a magnetoresistive response of the semiconductor over the mobility of the semiconductor.

2. The sensor of claim 1, wherein the varying mobility comprises Δμ; and
wherein the magnetoresistance response is dependent on ΔμH, where H is the magnetic field.

3. The sensor of claim 2, wherein the varying mobility comprises a mobility distribution centered approximately around zero mobility; and
wherein Δμ is a standard deviation of the mobility distribution.

4. The sensor of claim 3, wherein an average mobility of the semiconductor is approximately zero.

5. The sensor of claim 4, wherein the mobility distribution comprises a Gaussian distribution.

6. The sensor of claim 1, wherein the polycrystalline semiconductor comprises grains separated by grain boundaries; and
wherein the grain boundaries are in a range of approximately 0.1 micron to approximately 100 microns.

7. The sensor of claim 1, wherein the temperature range includes a lower temperature limit of approximately 200K.

8. The sensor of claim 7, wherein the temperature range includes an upper temperature limit of approximately a melting point of the semiconductor.

9. The sensor of claim 1, wherein the magnetoresistive response of the semiconductor stays constant or increases as temperature increases.

10. The sensor of claim 9, wherein the magnetoresistive response of the semiconductor increases as temperature increases.

11. The sensor of claim 1, wherein the magnetoresistive response of the polycrystalline semiconductor is substantially linear with the magnetic field above 1 tesla.

12. The sensor of claim 11, wherein the magnetoresistive response of the polycrystalline semiconductor is substantially linear with the magnetic field above 50 tesla.

13. The sensor of claim 1, wherein the semiconductor comprises an inhomogeneous structure on microscale that includes grains separated by grain boundaries and one or more elements segregated to grain boundary regions; and
wherein the one or more elements comprises an excess constituent of the semiconductor or an impurity element.

14. The sensor of claim 13, wherein the polycrystalline semiconductor is configured by grinding single crystal semiconductor and sintering the ground single crystal semiconductor.

15. The sensor of claim 13, where modifying at least one of grain size or grain boundary to volume fraction changes at least one characteristic of the magnetoresistance.

16. The sensor of claim 15, wherein the at least one characteristic of the magnetoresistance comprises at least one of temperature onset of the linear magnetoresistance response or magnitude of the magnetoresistance response.

17. The sensor of claim 1, wherein the semiconductor comprises a narrow-gap semiconductor.

18. The sensor of claim 17, wherein the narrow-gap semiconductor comprises InSb.

19. A sensor for measuring a magnetic field, the sensor comprising:
a semiconductor configured to have sufficiently low carrier density and sufficiently high carrier mobility to permit transition of carriers into an extreme quantum limit resulting in a resistance of the semiconductor to an applied magnetic field that is substantially linear for a predetermined temperature range.

20. The sensor of claim 19, wherein the semiconductor comprises InSb.

21. The sensor of claim 20, wherein an upper limit of the predetermined temperature range is approximately 175K.

22. The sensor of claim 19, wherein the semiconductor is configured by doping in order to generate a single band of low density, degenerate electrons or holes.
